(19) United States
(12) Patent Application Publication
(10) Pub. No.: US 2002/0070745 A1
(43) Pub. Date: Jun. 13, 2002

(54) Cooling system for burn-in unit

(76) Inventors: James E. Johnson, Houston, TX (US); Ronald J. Darcy, Houston, TX (US)

Correspondence Address: CONLEY ROSE & TAYON, P.C., P. O. BOX 3267, HOUSTON, TX, 77253-3267, US

(21) Appl. No.: 09/559,611

(22) Filed: Apr. 27, 2000

(51) Int. Cl. G01R 31/26

(52) U.S. Cl. 324/765

(57) ABSTRACT

A burn-in apparatus for burning-in or testing at least one device-under-test (DUT) that is mounted on a burn-in-board comprising a chamber, a board support affixed within the chamber so as to support a burn-in board in an installed position, a blower for creating a circulating gas flow in the chamber, a heat exchanger that removes heat generated during burn-in, and at least one gas flow linearizer upstream of the board support in the circulating gas flow. The linearizer has a first axis substantially parallel to the circulating gas flow and is at least of sufficient length in the direction of the first axis to substantially linearize the circulating gas flow in the vicinity of the installed burn-in board.

### RELATED APPLICATIONS

None.

### STATEMENT REGARDING FEDERALLY SPONSORED RESEARCH OR DEVELOPMENT

Not applicable.

### TECHNICAL FIELD OF THE INVENTION

The present invention relates generally to devices and methods for burn-in and testing of electronic components and more specifically to devices and methods for cooling these devices-under-test (DUT's) during the burn-in and test processes that ensures that newly-manufactured chips are suitable for use. Still more particularly, the invention relates to devices and methods for cooling multiple DUTs mounted on a plurality of burn-in boards and/or test or performance boards in a burn-in chamber by projecting a linearized air flow across the burn-in boards.

### BACKGROUND OF THE INVENTION

It is well-known in the art of chip manufacturing to test, and/or “burn-in” various electronic components before assembling them into a larger device. For example, computer chips are frequently individually connected in a burn-in or test system for the purpose of ensuring that all of the desired electronic circuits in each chip are operational. The burn-in/test process accelerates aging of the chips and thus allows defective chips to be identified and discarded early in the manufacturing process. This is desirable because it allows the manufacturer to avoid the expense that would otherwise be wasted in constructing a larger, more expensive device containing the defective chip. In addition to burn-in, computer chips and other integrated circuits may be subjected to various other testing operations. The term “testing” as used herein is intended to encompass and include burn-in and test operations.

In a typical burn-in or test operation, each chip being tested, hereinafter “device-under-test” or “DUT,” is connected to several electronic contacts. These contacts may take the form of “solder bumps” or wire leads coming out of the DUT. Each burn-in or test socket, hereinafter known as a test socket, has a corresponding set of contacts. Each DUT package as a different set of contacts. One package type takes the form of an array of small solder buttons that are positioned to correspond to socket leads on the under-surface of the DUT. The DUT is placed on an array of leads in the socket so that an electrical connection is made at each desired point and is typically held in place by a clamp or similar device on the socket. This device sometimes is used as a heat spreader. A typical burn-in board may have burn-in sockets for 6-18 DUTs for high power microprocessor devices or 120-256 DUTs for memory devices.

Burn-in and/or burn-in testing is typically carried out in a burn-in chamber. Each burn-in chamber contains mounting fixtures (racks and connectors) for several burn-in boards, which in turn support several DUTs. The burn-in boards include electrical leads for connecting the DUT to the burn-in system via the burn-in boards, and may include one or more cooling devices, such as heat sinks, for removing heat from the DUTs.

During the typical burn-in or test operation, heat is generated by the passage of current through each DUTs. Heretofore, DUTs were less powerful and, correspondingly, the amount of power consumed during burn-in of a computer chip was relatively small. For this reason, the amount of heat generated was such that burn-in devices could be air-cooled in most cases. With the advent of newer, more powerful chips, the amount of heat generated during burn-in has increased ten-fold, from about 1-5 watts, to about 10-50 watts or more. It is contemplated that some chips may generate as much as 100 watts in the near future.

In addition, the increasing cost of chip packaging has motivated manufacturers to advance the burn-in step so that it is carried out before, rather than after, final packaging. This allows manufacturers to save the cost of packaging a defective chip, but means that the burn-in operation must be carried out on partially packaged chips, where the silicon die itself may be exposed. Partially packaged chips are less robust and more susceptible to damage than fully packaged chips. Thus, the burn-in operation cannot subject the DUTs to excessive or uneven forces.

Because the burn-in must be carried out at a controlled temperature, and because the chips cannot be exposed to temperature extremes, it is imperative that the significant heat generated during the burn-in or test operation be removed. Air cooling does not provide sufficient cooling without a very large heat sink. Liquid cooling, using an electrically insulating fluid has been tried, but has proven nonviable for very high power DUTs. At the same time, burning-in or testing a partially packaged chip raises new considerations over burning-in or testing a fully packaged chip. For example, partially packaged chips are not typically adapted to readily dump heat at the required rate. Various advances have been made in the ability to remove heat from each DUT. Some of these are disclosed in copending application Ser. No. 09/167,238, filed Oct. 6, 1998 and entitled “Burn-In Board Capable of High Power Dissipation” and Ser. No. 09/167,295, filed Oct. 6, 1998 and entitled “Burn-In Board with Adaptable Heat Sink Device,” both of which are hereby incorporated by reference in their entireties. This heat is removed by conduction into a heat sink, heat exchanger or other cooling device.

In addition to the need to remove large amounts of heat during burn-in, the close tolerances to which chips are being manufactured require that the temperature in the burn-in chamber be tightly controlled. Specifications for burn-in chambers may require that the air temperature within the chamber be controlled to within ±3° C. and that the temperature difference between any two points within the chamber be no more than 6° C.

Hence, it is desired to provide a burn-in chamber that is capable of uniformly removing at least 10-100 watts of heat from each of several chips, while maintaining the temperature of each DUT within a narrow desired range. Furthermore, the preferred system should be capable of uniformly maintaining the DUTs within the prescribed temperature throughout the entire burn-in unit. These objectives require that the system be capable of providing adequate uniform cooling to every DUT within the burn-in unit and substantially eliminating hot or cool spots in the vicinity of DUTs. It is further desired to provide a burn-in unit that is commercially viable in terms of cost, labor and reliability.

### SUMMARY OF THE INVENTION

The present burn-in chamber is capable of uniformly removing at least 10-100 watts of heat from each of several chips, while maintaining the temperature of each DUT within a narrow, desired range. The present device is also capable of uniformly maintaining the DUTs within the prescribed temperature throughout the entire burn-in unit by cooling every DUT within the burn-in unit while substantially eliminating hot or cool spots in the vicinity of DUTs. The present burn-in chamber includes an impeller housed within the chamber, for circulating a stream of air through the burn-in chamber, and a plurality of linearizers that reduce turbulence inside the chamber and therefore ensure a consistent, uniform flow of air across the DUTs.

The linearizing devices incorporated into the present chamber include curved baffles that facilitate change in direction of the air or other gas flow and channelized plates positioned at intervals in the circulating flow of air, which serve to reduce turbulence in the flow. A plurality of heat exchangers are also positioned at intervals throughout the burn-in chamber to remove heat produced during burn-in and thereby maintain the temperature substantially uniform throughout the chamber.

### BRIEF DESCRIPTION OF THE DRAWINGS

For a more complete understanding of the preferred embodiments, reference will now be made to the accompanying drawings, in which:

FIG. 1 is a front elevation of a cabinet constructed in accordance with one preferred embodiment of the invention;

FIG. 2 is a view of the inside of cabinet of FIG. 1;

FIG. 3 is an enlarged view of a preferred heat exchange system for use in the cabinet of FIG. 1;

FIGS. 4A and 4B are enlarged plan and isometric views, respectively, of a portion of a linearizer panel for use in the cabinet of FIG. 1;

FIG. 5 is a second preferred embodiment of the inside of a cabinet constructed in accordance with the present invention;

FIG. 6 is a third preferred embodiment of the inside of a cabinet in accordance with the present invention;

FIG. 7 is a fourth preferred embodiment of the inside of a cabinet in accordance with the present invention; and

FIG. 8 is a schematic diagram of an alternative embodiment of a liquid heat exchange system in accordance with the present invention.

### NOTATIONS AND NOMENCLATURE

Certain terms used throughout the following description and claims refer to particular electronic devices. As one skilled in the art will appreciate, people may refer to components by different names. This document does not intend to distinguish between components that differ in name but not function. In the following discussion and in the claims, the terms “including” and “comprising” are used in an open-ended fashion, and thus should be interpreted to mean “including, but not limited to . . . ”.

In addition, the terms “electronic component,” “computer chip,” and “chip” are intended to include a variety of devices, such as integrated circuits, microprocessors, microchips, memory chips, or any other similar device. These terms, while technically distinguishable, are used interchangeably for the purposes of this document unless specified otherwise for a specific use. The acronym DUT, for “device under test,” is used generically herein to refer to all such items.

Additionally, identical reference numerals have been used in the respective figures to indicate corresponding items in each embodiment.

### DETAILED DESCRIPTION OF THE PREFERRED EMBODIMENTS

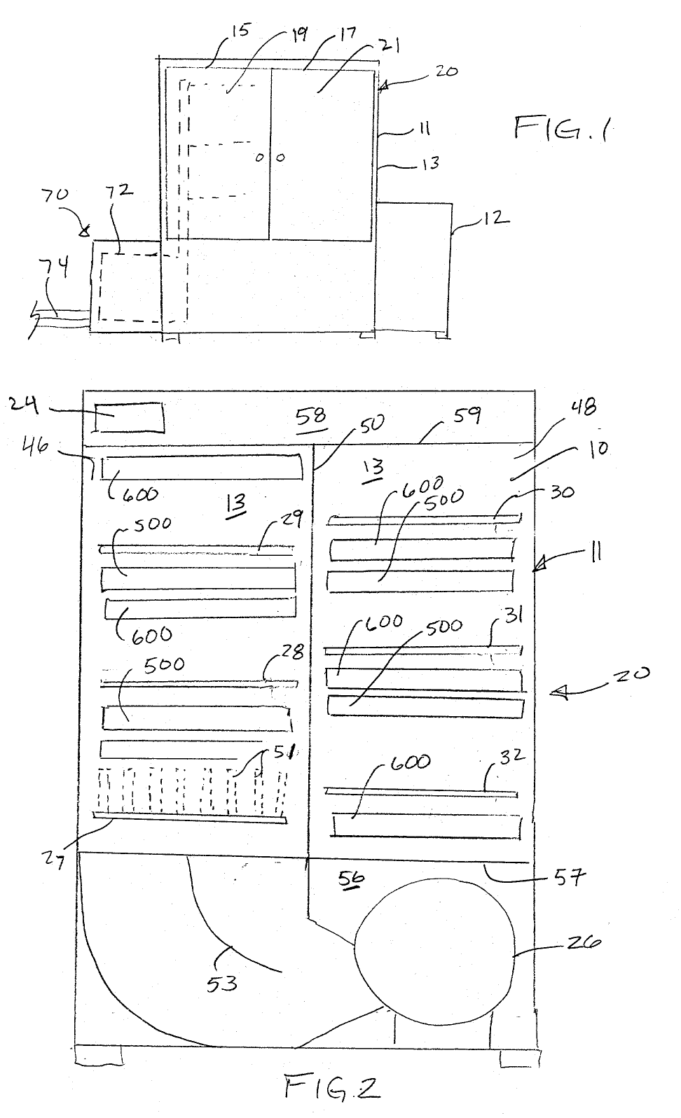

Referring initially to FIG. 1, a burn-in apparatus constructed in accordance with a preferred embodiment includes a cabinet 20 and a cooling system 70. Cabinet 20 includes an instrumentation and power supply portion 12 and a temperature-controlled chamber portion 11. Chamber portion 11 includes a chamber 10 (FIG. 2) generally enclosed on six sides by chamber walls 13, which are preferably made of a thermally insulating material. The front portion of wall 13 has at least one and preferably, at least two access openings 15, 17 for permitting access to the interior of chamber 10. Access openings 15, 17 are covered by doors 19, 21, respectively, such that when doors 19, 21 are closed, chamber 10 is substantially thermally insulated from the environment outside cabinet 20.

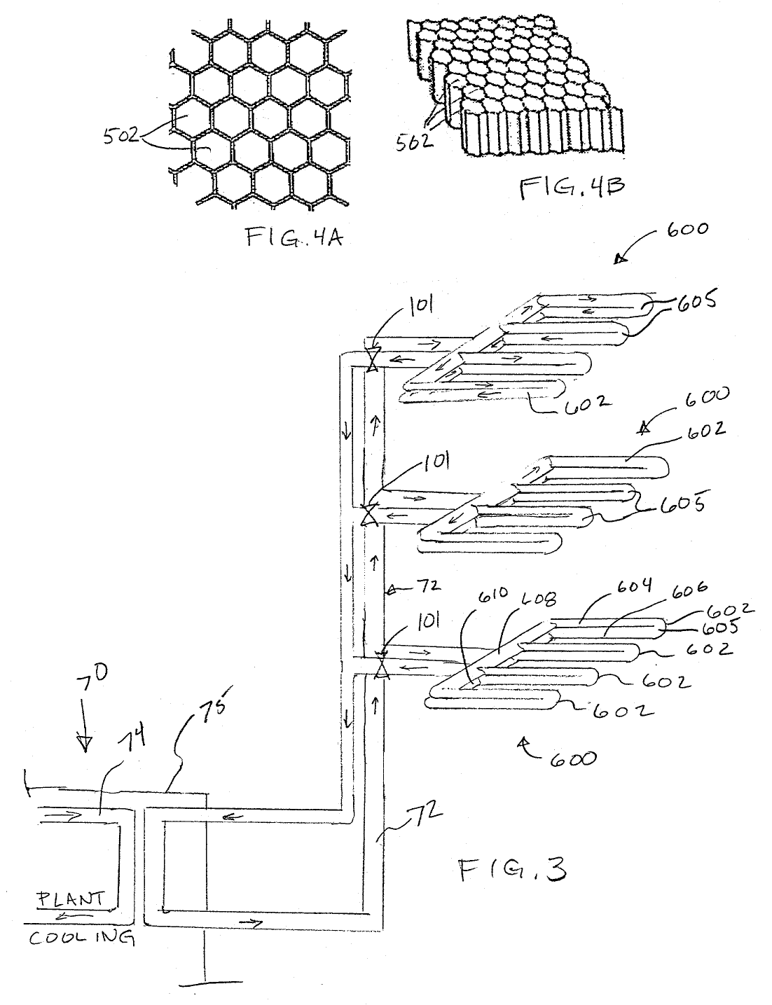

Cooling system 70 preferably comprises a closed liquid cooling loop 72 and a plant cooling loop 74. Heat absorbed in cabinet 20 by liquid in closed loop 72 is then transferred to liquid in plant cooling loop 74 in a liquid/liquid heat exchanger 75 (FIG. 3), using any suitable heat exchange technique. Cooling system 70 is described in detail below with respect to FIG. 3.

Referring particularly to FIG. 2, chamber 10 is divided into left and right sections 46, 48, respectively, by a mid-chamber wall 50 that extends substantially vertically through the center of chamber 10. Wall 50 extends through the entire depth of chamber 10, with the top of wall 50 terminating below the top of chamber 10 so as to form an upper duct 58 and the bottom of wall 50 terminating above the bottom of chamber 10 so as to form a lower duct 56. In a preferred embodiment, upper duct 58 is defined by a chamber ceiling panel 59 and lower duct 56 is defined by chamber floor panel 57. At least one heater 24 is preferably mounted in upper duct 58. In a preferred embodiment, heaters 24 are mounted in upper duct 58 and in lower duct 56.

A plurality of board supports 27, 28, 29, 30, 31, and 32 are mounted within chamber 10, which preferably attach to and extend through the rear chamber wall 13. Board supports 27, 28, 29, 30, 31, and 32 are each capable of supporting a plurality of burn-in boards 51 (shown in phantom) in a fixed position within chamber 10 such that they are spaced apart from chamber walls 13 and mid-chamber wall 50 and are spaced apart from one another such that air can flow between them. Board supports 27-32 also provide connections (not shown) for electrically interconnecting the burn-in boards to the controls and the power supplies. Board supports 27-32 are preferably identical to one another and are uniformly spaced from one another throughout the middle portion of chamber 10.

According to a preferred embodiment, plurality of heat exchangers 600 and a plurality of gas flow linearizers 500 are positioned between adjacent ranks of board supports. It is preferred to provide a heat exchanger downstream of each board support and to provide a linearizer at least upstream and preferably both upstream and downstream of each heat exchanger.

Referring briefly to FIG. 3, each heat exchanger 600 preferably comprises a manifolded series of cooling fluid loops, 602. Each loop 602 includes an outbound leg 604 and an inbound leg 606, connected by a U-shaped cusp 605. Outbound leg 604 and inbound leg 606 are preferably positioned vertically relative to each other, so that they are aligned in the direction of air flow within chamber 10. Outbound legs 604 and inbound legs 606 are manifolded at 608, 610, respectively, and manifolds 608 and 610 connect in turn to closed coolant loop 72. The use of outbound legs 604 and inbound legs 606 results in the average temperature across the width of each heat exchanger 600 substantially uniform. It is preferred that the several heat exchangers 600 be connected in parallel across cooling loop 72, as shown, so that the coolant flowing into all of the inbound legs 606 in chamber 10 is at the same temperature. It is further preferred to provide a valve 101 on either the inbound or the outbound side of each heat exchanger 600. Valves 101 are preferably controlled in response to a temperature feedback control loop (not shown). Temperature measurements that are input into the control loop can be made by sensors that sense the temperature of the water leaving each exchanger 600, or sensors positioned inside the chamber so as to sense the air temperature in the vicinity of the burn-in boards. It will be understood that the foregoing coolant flow system can be modified without departing from the scope of the present invention.

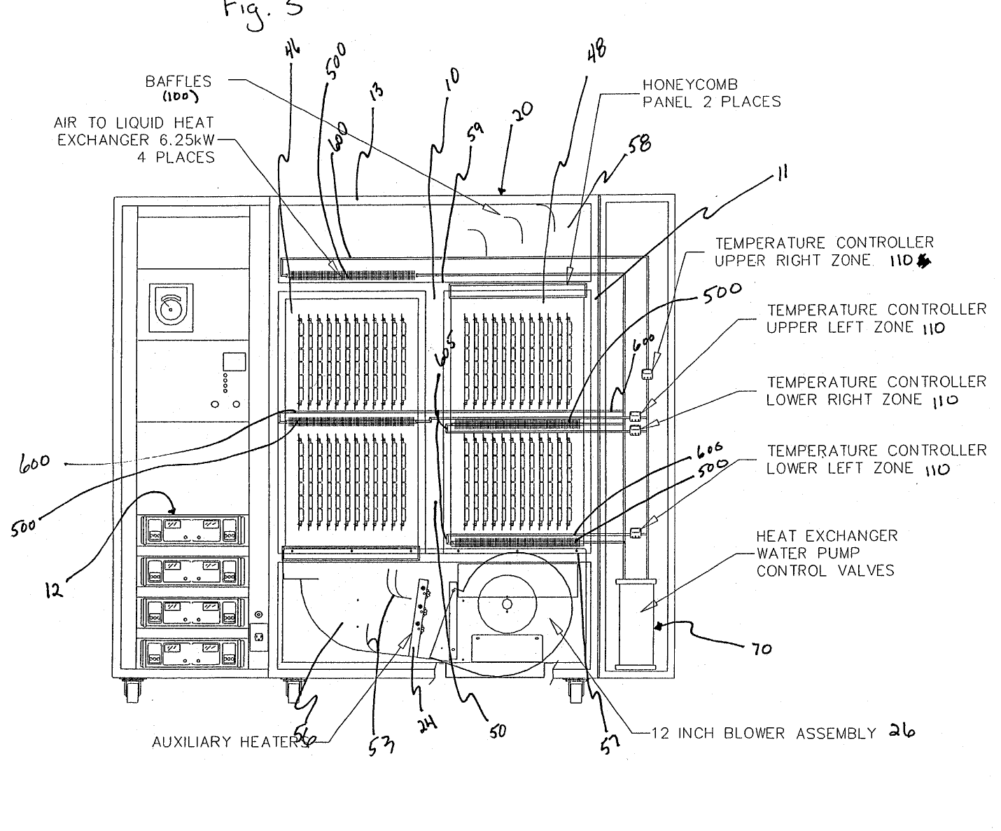

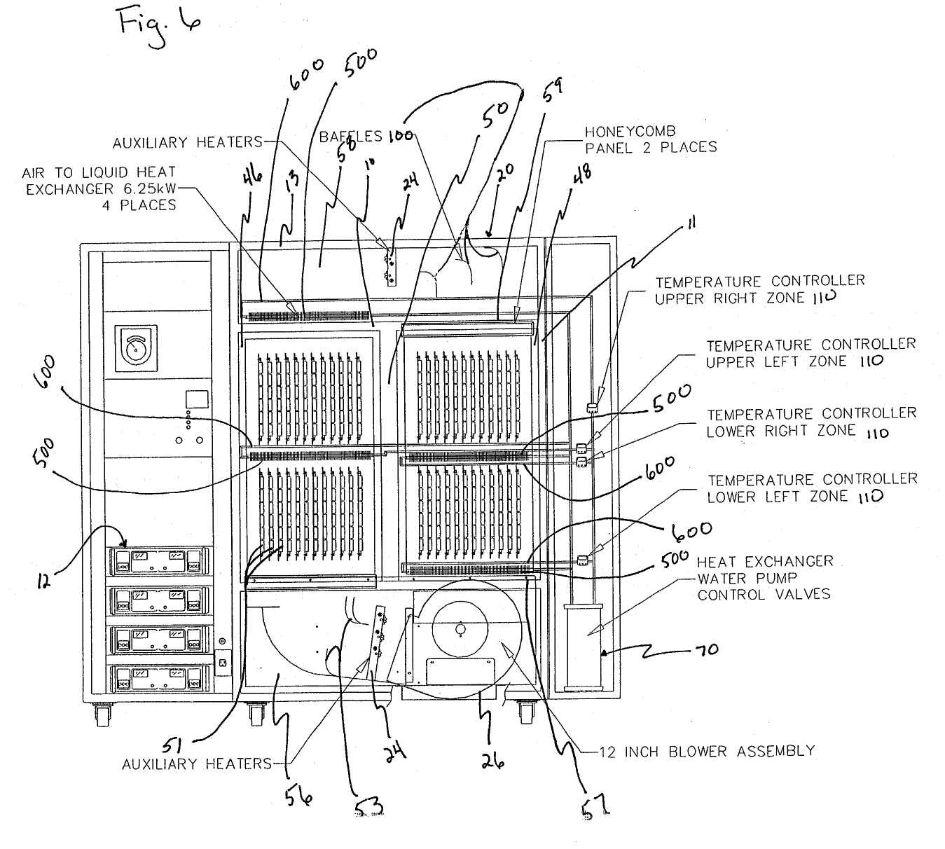

Referring now to FIGS. 4A and 4B, the preferred linearizers 500 are panels comprising a plurality of hexagonal cells 502. Each cell forms an unobstructed passage along the length of the linearizer. The cells substantially eliminate turbulence in the air flow and therefore significantly reduce eddies and channels that can cause pressure variations and/or cause hot or cool spots in chamber 10. The length of the linearizers 500, as measured in the direction of air flow, may vary according to available space or as is physically required by the gas used to cool the DUTs. Up to a point, the longer the linearizer, the more effectively it will eliminate turbulence. At the same time, space constraints prevent the use of linearizers longer than about 4 inches. In one preferred embodiment, the length of each linearizer is about 2 inches. In one preferred embodiment, chamber ceiling panel 59 and chamber floor panel 57 are constructed of the same cellular material and function as additional linearizers.

The preferred heat exchangers 600 are positioned downstream of each board support and arranged for uniform removal of the heat generated during burn-in. Preferably, the heat exchangers 600 et seq. are in thermal contact with a temperature sensor (not shown) and the flow of coolant through each heat exchanger is individually adjustable to maintain a temperature gradient of no more than 6° C. between any two points inside chamber 10. A preferred coolant comprises chilled water or brine. Although it is preferred that the coolant for each heat exchanger 600 be provided from closed coolant loop 72, it will be understood that other configurations, such as those including multiple coolant systems and series rather than parallel cooling loops, are also suitable.

Referring again to FIG. 2, an impeller 26 is preferably housed in lower duct 56, and provides the motive force for the desired movement of air through cabinet 20. Impeller 26 preferably comprises a centrifugal blower mounted in lower duct 56 so as to force air laterally across the bottom of cabinet 20, up through left section 46, past heater 24, through upper duct 58, and back down through right section 48 of chamber 10. At least one, and preferably two or more curved baffles 53 serve to guide the flow of air in lower duct 56 so that it changes direction smoothly and with a minimum of turbulence. If desired, additional baffles (not shown) may be provided in upper duct 58. Preferably, pump 26 drives the air at a rate of approximately 1,400-2,000 linear feet per minute. This velocity of air flow coupled with the linearizers 500 and the heat exchangers 600 will normally be sufficient to maintain a narrow temperature gradient even in a loaded chamber, i.e., a chamber fully loaded with components undergoing burn-in.

As described above, auxiliary heaters 24 are provided for heating the air and components inside chamber 10 when it is desired to operate the burn-in system at a temperature above ambient. In one preferred embodiment, heaters 24 comprise a ceramic/wire wound type heater. These and other suitable heater types are well known in the art and are replaceable.

According to one preferred embodiment, in operation, air flows from impeller 26, along baffles 53 up through the left side 46, by going through chamber floor panel 57, across board support 27, through first heat exchanger 600, through a first linearizer 500, across board support 28, and through additional heat exchangers, linearizers, and board supports, until it passes into upper duct 58. The air is directed across the top of cabinet 20 through upper duct 58. As the air flows down through the right side 48, it flows through a corresponding series of linearizers, heat exchangers and board supports. The air then enters lower duct 56 and is recirculated.

Referring now to FIG. 5, an alternative embodiment of the present invention comprises substantially the same components as the embodiment shown in FIG. 2, but the components are configured somewhat differently. Specifically, as air flows from impeller 26, it is heated by heating unit 24 before being deflected by baffles 53 up through left section 46. As the air flows through upper duct 58 it is deflected downward by upper baffles 100 down through right section 48. FIG. 5 also includes a plurality of temperature controllers 110 to monitor and/or control the temperature in each respective quadrant of the chamber. The temperature controllers 110 are preferably adjustable to maintain a temperature gradient of no more than 6° C. between any two points inside the chamber.

The embodiment of FIG. 6 is similar to the embodiment of FIG. 5, but includes a second auxiliary heater 24 in upper duct 58. Auxiliary heater 24 can, if necessary, heat the air before it flows down through right section 48.

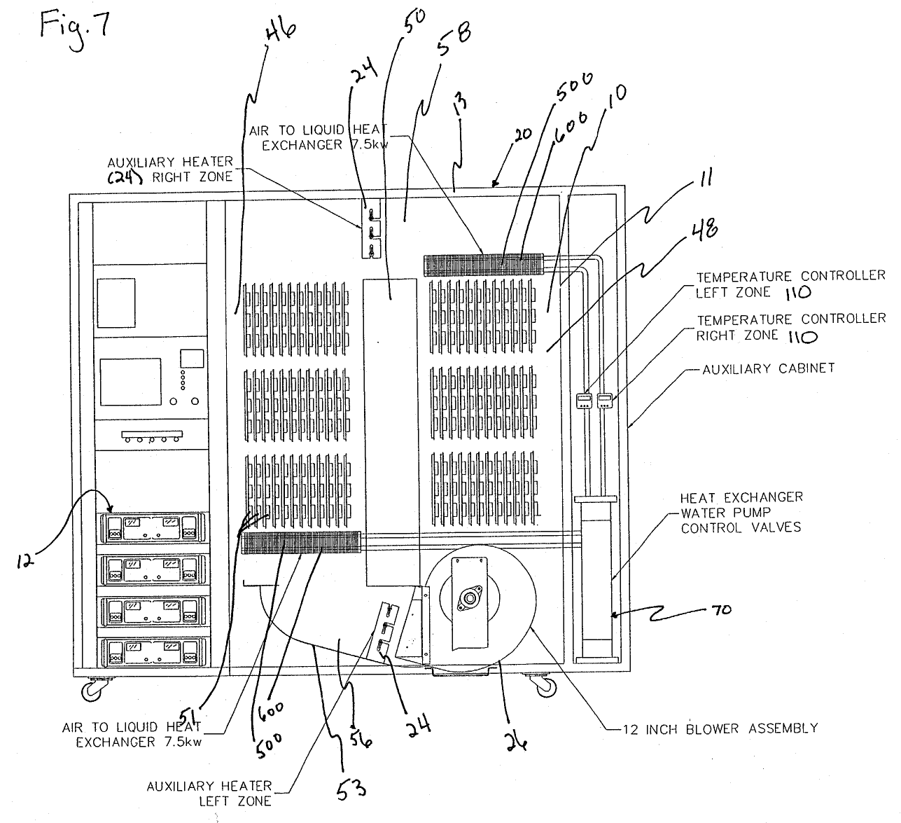

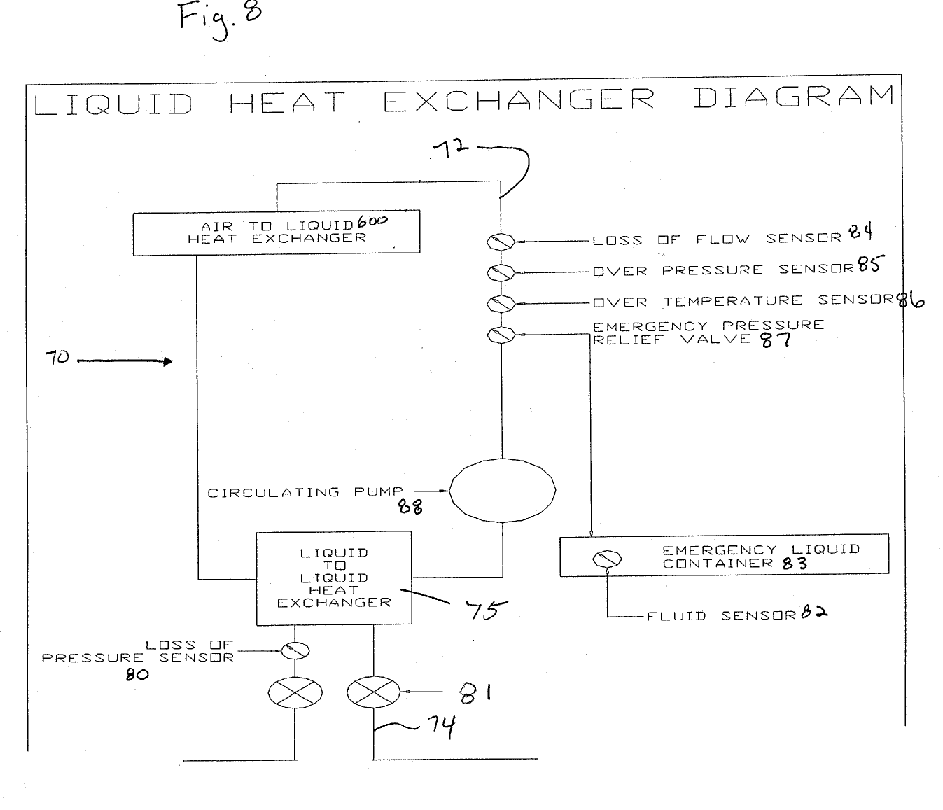

Referring now to FIG. 7 still another preferred embodiment of the invention is shown. In FIG. 7, chamber 10 is divided into left and right sections 46, 48, respectively, by a mid-chamber wall 50 that extends substantially vertically through the center of chamber 10 and serves as a spacer between left and right sections 46, 48. In this preferred embodiment, heaters 24 are mounted in both upper duct 58 and in lower duct 56.

As before, a plurality of board supports (not shown) are mounted within chamber 10, and are each capable of supporting a plurality of burn-in boards 51 in a fixed position within chamber 10 such that they are spaced apart from chamber walls 13 and mid-chamber wall 50 and are spaced apart from one another such that air can flow between them. Board supports (not shown) also provide connections (not shown) for electrically interconnecting the burn-end boards to the controls and the power supplies.

According to the preferred embodiment of FIG. 7, heat exchangers 600 and the gas flow linearizers 500 are positioned near the bottom of right section 46 upstream of baffle 53 and near the top of right section 48 in order to cool and linearize the air flow as it flows up left section 46 and down right section 48, respectively. Temperature controllers 110 are provided for each heat exchanger monitor the temperature of the air flowing across each heat exchangers 600 and to control the volume of water flowing through each exchanger 600. The temperature controllers are preferably adjustable to maintain a temperature gradient of no more than 6° C. between any two points inside the chamber.

As described above with respect to FIG. 3, the cooling system is preferably a closed loop cooling system 70 containing air-to-liquid heat exchangers 600 through which liquid coolant is circulated. Referring now to FIG. 8, a alternative embodiment of a preferred liquid cooling system comprises closed coolant loop 72, which includes a pump 88, one or more air/liquid heat exchangers 600, and sensors 84-86, and plant coolant loop 74, which includes a pressure sensor 80 and an emergency shutoff 81. Heat is exchanged between coolant loop 72 and plant coolant loop 74 in liquid/liquid heat exchanger 75. Sensors 84-86 preferably include a loss of flow sensor 84, an over pressure sensor 85, and an over temperature sensor 86, which are used to determine whether the coolant flow has ceased or decreased, the pressure is too great, or the temperature is too great, respectively. In addition, an emergency pressure relief valve 87 is also preferably included in loop 72, to relieve pressure in the event of pressure increase above the desired pressure. Any liquid leaving the loop through the emergency pressure relief valve 87 is captured by the emergency liquid container 83, which contains a fluid sensor 82 to determine if the emergency relief valve 87 has been actuated.

Although the apparatus described herein has been found to be most satisfactory and preferred, many variations in structure are possible without departing from the spirit of the invention. Because many varying embodiments fall within the scope of the inventive concept herein disclosed and many modifications may be made to the preferred embodiment herein described in detail in accordance with the descriptive requirements without departing from the invention, the details herein set forth are to be interpreted and understood as illustrative and not in a limiting sense.

What is claimed is:

1. A burn-in apparatus for performing burn-in on a device-under-test (DUT), the DUT being mounted on a burn-in-board, comprising:
a chamber;
a board support affixed within the chamber so as to support a burn-in board in an installed position;
a blower for creating a circulating gas flow in said chamber;
a heat exchanger for removing heat generated during burn-in; and
a gas flow linearizer upstream of said board support in said circulating gas flow; said linearizer having a first axis substantially parallel to the circulating gas flow and being at least of sufficient length in the direction of the first axis to substantially linearize the circulating gas flow in the vicinity of the installed burn-in board.

2. The burn-in apparatus of claim 1 wherein said heat exchanger is positioned downstream of the installed burn-in board.

3. The burn-in apparatus of claim 1 further comprising a plurality of board supports affixed within the chamber.

4. The burn-in apparatus of claim 3, further comprising a heat exchanger corresponding to each board support.

5. The burn-in apparatus of claim 3 wherein a linearizer is positioned upstream of each board support.

6. The burn-in apparatus of claim 3 wherein each heat exchanger is positioned downstream of its corresponding board support.

7. The burn-in apparatus of claim 3 wherein each board support is adapted to support a plurality of burn-in boards.

8. The burn-in apparatus of claim 1 wherein said gas flow linearizer comprises a plurality of linearizing cells.

9. The burn-in apparatus of claim 1, further including at least one curved baffle between said blower and said board supports.

10. The burn-in apparatus of claim 1, wherein said chamber is configured to cause circulating air flow from said blower through said board and said heat exchanger and includes at least one flow re-directing duct.

11. The burn-in apparatus of claim 10, further including at least one curved baffle in said flow re-directing duct.

12. A method for providing substantially uniform cooling to a plurality of devices-under-test (DUT), the DUT's being mounted on burn-in-boards distributed throughout a burn-in apparatus, comprising:
(a) providing a gas stream across the respective burn-in boards;
(b) providing a gas flow linearizer having a first axis, wherein the gas flow linearizer is arranged upstream of a burn-in board and such that the gas stream flows through the gas flow linearizer substantially parallel to the first axis, and wherein the gas flow linearizer is at least of a sufficient length in the direction of the first axis to substantially linearize the gas flow in the vicinity of the burn-in board; and
(c) providing a heat exchanger corresponding to each burn-in board and in thermal contact with each burn-in board for removing heat generated during burn-in.

13. The method of claim 12 wherein each heat exchanger is positioned upstream of a corresponding burn-in board.

14. The burn-in apparatus of claim 12 wherein said gas flow linearizer comprises a plurality of linearizing cells.

15. A means for substantially uniformly cooling a plurality of devices-under-test (DUT's) during burn-in, each DUT being mounted on a burn-in board, comprising:
a chamber;
means for supporting a plurality of burn-in boards within the chamber;
means for creating a circulating gas flow throughout the chamber;
means for removing heat from the burn-in board during burn-in; and
means for linearizing the circulating gas flow across each burn-in board.

16. An apparatus for uniformly cooling a plurality of devices-under-test (DUT's) attached to burn-in boards within a burn-in unit comprising:
a plurality of board supports adapted to receive the burn-in boards;
a pump for creating a gas flow across the burn-in boards;
a gas flow linearizer having a first axis; wherein the gas flow linearizer is arranged upstream of the burn-in board such that the gas flow flows through the gas flow linearizer in substantially the direction of the first axis; and wherein the gas flow linearizer is of a sufficient length in the direction of the first axis to substantially linearize the gas flow; and
a heat exchanger in thermal contact with and corresponding to each burn-in board for removing heat generated during burn-in.

17. The apparatus of claim 16 wherein said heat exchanger comprises a coolant loop.

18. The apparatus of claim 16 wherein each heat exchanger comprises a coolant loop and said coolant loops are manifolded together and connected in parallel across a cooling system.

19. The apparatus of claim 16 wherein said gas flow linearizer comprises a plurality of cells.

20. A burn-in chamber for substantially uniformly cooling a plurality of devices-under-test (DUT's), the DUT's being attached to a plurality of burn-in boards, comprising:
a plurality of board supports for supporting said boards inside the chamber; and
an impeller for creating a circulating flow of air within the chamber;
wherein the pressure of the circulating flow of air does not differ by more than 6 inches of water between any two pints inside the chamber.

21. The chamber according to claim 20 wherein the velocity of the circulating flow of air is at least 1400 linear feet per minute.
